(19) United States
(12) Patent Application Publication
(10) Pub. No.: US 2004/0127030 A1
(43) Pub. Date: Jul. 1, 2004

(54) Method and apparatus for monitoring a material processing system

(75) Inventor: James E. Klekotka, Mesa, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/331,330

(22) Filed: Dec. 31, 2002

(51) Int. Cl. H01L 21/00; H01L 21/302; H01L 21/461

(52) U.S. Cl. 438/689

(57) ABSTRACT

The present invention presents an improved apparatus and method for monitoring a material processing system, wherein the material processing system includes a processing tool, a number of RF-responsive status sensors coupled to the processing tool to generate and transmit status data, and a sensor interface assembly (SIA) configured to receive the status data from the plurality of RF-responsive status sensors.

### CROSS-REFERENCE TO RELATED APPLICATIONS

This application is related to co-pending applications 10______ Attorney Docket No. 231748US6YA, filed on even date herewith, entitled “Method and Apparatus for Monitoring a Material Processing System”; 10/______, Attorney Docket No. 231750US6YA, filed on even date herewith, entitled “Method and Apparatus for Monitoring a Material Processing System”; 10/______, Attorney Docket No. 231227US6YA, filed on even date herewith, entitled “Method and Apparatus for Monitoring Parts in a Material Processing System”; and 10/______, Attorney Docket No. 231228US6YA, filed on even date herewith, entitled “Method and Apparatus for Monitoring a Plasma in a Material Processing System”. The entire contents of each of these applications are herein incorporated by reference.

### FIELD OF THE INVENTION

The present invention relates to monitoring a process in a processing system and, more particularly, to monitoring a process using a monitoring device having an integral transmission device.

### BACKGROUND OF THE INVENTION

The fabrication of integrated circuits (IC) in the semiconductor industry typically employs plasma to create and assist surface chemistry within a plasma reactor necessary to remove material from and deposit material to a substrate. In general, plasma is formed within the plasma reactor under vacuum conditions by heating electrons to energies sufficient to sustain ionizing collisions with a supplied process gas. Moreover, the heated electrons can have energy sufficient to sustain dissociative collisions and, therefore, a specific set of gases under predetermined conditions (e.g., chamber pressure, gas flow rate, etc.) are chosen to produce a population of charged species and chemically reactive species suitable to the particular process being performed within the chamber (e.g., etching processes where materials are removed from the substrate or deposition processes where materials are added to the substrate).

During, for example, an etch process, monitoring the plasma processing system can be very important when determining the state of a plasma processing system and determining the quality of devices being produced. Additional process data can be used to prevent erroneous conclusions regarding the state of the system and the state of the products being produced. For example, the continuous use of a plasma processing system can lead to a gradual degradation of the plasma processing performance and ultimately to complete failure of the system. Additional process related data and tool related data will improve the management of a material processing system and the quality of the products being produced.

### SUMMARY OF THE INVENTION

The present invention provides an apparatus and method for monitoring a process in a processing system and, more particularly, to a process monitoring device having an integral transmission device and a method for monitoring a process in a processing system using a process monitoring device having an integral transmission device.

The present invention also provides an apparatus and method for monitoring a plasma process in a material processing system and, more particularly, to a plasma monitoring device having an integral transmission device and a method for monitoring a plasma process in a material processing system using a plasma monitoring device having an integral transmission device.

The present invention also provides a means for monitoring a process in a material processing system that includes at least one RF-responsive sensor coupled to at least one sensor interface assembly (SIA).

### BRIEF DESCRIPTION OF THE DRAWINGS

These and other advantages of the invention will become more apparent and more readily appreciated from the following detailed description of the exemplary embodiments of the invention taken in conjunction with the accompanying drawings, where:

FIG. 1 illustrates a simplified block diagram for a material processing system in accordance with an embodiment of the present invention;

FIG. 2 shows a simplified block diagram of a RF-responsive status sensor and a sensor interface assembly (SIA) in accordance with an embodiment of the present invention;

FIGS. 3a-3c show simplified block diagrams of a RF-responsive status sensor in accordance with embodiments of the present invention;

FIGS. 4a-4c show simplified block diagrams of a RF-responsive status sensor in accordance with additional embodiments of the present invention;

FIGS. 5a-5c show simplified block diagrams of a RF-responsive status sensor in accordance with additional embodiments of the present invention;

FIGS. 6a-6c show simplified block diagrams of a sensor interface assembly in accordance with embodiments of the present invention;

FIGS. 7a-7c show simplified block diagrams of a sensor interface assembly in accordance with additional embodiments of the present invention;

FIGS. 8a-8c show simplified block diagrams of a sensor interface assembly in accordance with additional embodiments of the present invention; and

FIG. 9 illustrates a method for monitoring a material processing system according to an embodiment of the present invention.

### DETAILED DESCRIPTION OF AN EMBODIMENT

The present invention provides an improved material processing system that can include a processing tool, which can comprise one or more process chambers. In addition, the processing system can include a plurality of RF-responsive status sensors that are coupled to the processing tool to generate and transmit status data and at least one SIA configured to receive the status data from at least one of the plurality of RF-responsive status sensors.

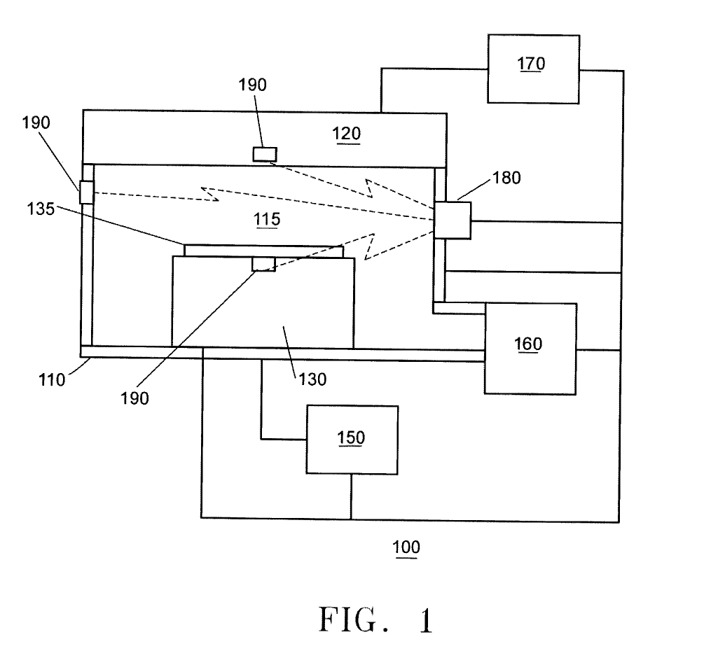

FIG. 1 illustrates a simplified block diagram for a material processing system in accordance with an embodiment of the present invention. For example, material processing system 100 can comprise an etch system, such as an plasma etcher. Alternately, material processing system 100 can comprise a photoresist coating system such as a photoresist spin coating system, and/or material processing system 100 can comprise a photoresist patterning system such as a lithography system. In another embodiment, material processing system 100 can comprise a dielectric coating system such as a spin-on-glass (SOG) or spin-on-dielectric (SOD) system. In another embodiment, material processing system 100 can comprise a deposition chamber such as a chemical vapor deposition (CVD) system, a physical vapor deposition (PVD) system, a atomic layer deposition (ALD) system, and/or combinations thereof. In an additional embodiment, material processing system 100 can comprise a thermal processing system such as a rapid thermal processing (RTP) system. In another embodiment, material processing system 100 can comprises a batch diffusion furnace or other semiconductor processing system.

In the illustrated embodiment, material processing system 100 comprises processing chamber 110, upper assembly 120, substrate holder 130 for supporting substrate 135, pumping system 160, and controller 170. For example, pumping system 160 can provide a controlled pressure in processing chamber 110. For example, processing chamber 110 can facilitate the formation of a processing gas in a process space 115 adjacent substrate 135. The material processing system 100 can be configured to process 200 mm substrates, 300 mm substrates, or larger substrates. Alternately, the material processing system can operate by generating plasma in one or more processing chambers.

Substrate 135 can be, for example, transferred into and out of processing chamber 110 through a slot valve (not shown) and chamber feed-through (not shown) via robotic substrate transfer system where it can be received by substrate lift pins (not shown) housed within substrate holder 130 and mechanically translated by devices housed therein. Once substrate 135 is received from substrate transfer system, it can be lowered to an upper surface of substrate holder 130.

Substrate 135 can be, for example, affixed to the substrate holder 130 via an electrostatic clamping system. Furthermore, substrate holder 130 can further include a cooling system including a re-circulating coolant flow that receives heat from substrate holder 130 and transfers heat to a heat exchanger system (not shown), or when heating, transfers heat from the heat exchanger system. Moreover, gas can, for example, be delivered to the back-side of substrate 135 via a backside gas system to improve the gas-gap thermal conductance between substrate 135 and substrate holder 130. Such a system can be utilized when temperature control of the substrate is required at elevated or reduced temperatures. In other embodiments, heating elements, such as resistive heating elements, or thermoelectric heaters/coolers can be included.

In alternate embodiments, substrate holder 130 can, for example, further comprise a vertical translation device (not shown) that can be surrounded by a bellows (not shown) coupled to the substrate holder 130 and the processing chamber 110, and configured to seal the vertical translation device from the reduced pressure atmosphere in processing chamber 110. Additionally, a bellows shield (not shown) can, for example, be coupled to the substrate holder 130 and configured to protect the bellows. Substrate holder 130 can, for example, further provide a focus ring (not shown), a shield ring (not shown), and a baffle plate (not shown).

In the illustrated embodiment, shown in FIG. 1, substrate holder 130 can comprise an electrode (not shown) through which RF power can be coupled to the process gasses in process space 115. For example, substrate holder 130 can be electrically biased at a RF voltage via the transmission of RF power from RF system 150. In some cases, a RF bias can be used to heat electrons to form and maintain plasma. A typical frequency for the RF bias can range from 1 MHz to 100 MHz. For example, semiconductor processing systems that use 13.56 MHz for plasma processing are well known to those skilled in the art.

As shown in FIG. 1, upper assembly 120 can be coupled to the processing chamber 110 and configured to perform at least one of the following functions: provide a gas injection system, provide a capacitively coupled plasma (CCP) source, provide an inductively coupled plasma (ICP) source, provide a transformer-coupled plasma (TCP) source, provide a microwave powered plasma source, provide an electron cyclotron resonance (ECR) plasma source, provide a Helicon wave plasma source, and provide a surface wave plasma source.

For example, upper assembly 120 can comprise an electrode, an insulator ring, an antenna, a transmission line, and/or other RF components (not shown). In addition, upper assembly 120 can comprise permanent magnets, electromagnets, and/or other magnet system components (not shown). Also, upper assembly 120 can comprise supply lines, injection devices, and/or other gas supply system components (not shown). Furthermore, upper assembly 120 can comprise a housing, a cover, sealing devices, and/or other mechanical components (not shown).

In an alternate embodiment, processing chamber 110 can, for example, further comprise a chamber liner (not shown) or process tube (not shown) for protecting the processing chamber 110 from a processing plasma in the process space 115. In addition, processing chamber 110 can comprise a monitoring port (not shown). A monitoring port can, for example, permit optical monitoring of process space 115.

Material processing system 100 also comprises at least one measuring device having an integral transmission means. As shown in the illustrated embodiment, at least one RF-responsive status sensor 190 can be used to generate and transmit data such as status data. For example, chamber 110 can comprise at least one RF-responsive status sensor 190, and/or upper assembly 120 can comprise at least one RF-responsive status sensor 190, and/or substrate holder can comprise at least one RF-responsive status sensor 190.

Material processing system 100 also comprises at least one interface device having an integral reception means. As shown in FIG. 1, a sensor interface assembly (SIA) 180 can be used to communicate with at least one RF-responsive status sensor 190. For example, SIA 180 can receive the status data.

In one embodiment, RF-responsive status sensor 190 can comprise a status sensor (not shown) and an integral transmitter (not shown), and SIA 180 can comprise an integral receiver (not shown). RF-responsive status sensor 190 can use the transmitter to send data, and the SIA 180 can use the receiver to receive the transmitted data. RF-responsive status sensors 190 can operate using the same or different frequencies, and SIA 180 can operate using one or more frequencies.

Material processing system 100 also comprises a controller 170. Controller 170 can be coupled to chamber 110, upper assembly 120, substrate holder 130, RF system 150, pumping system 160, and SIA 180. The controller can be configured to provide control data to the SIA and receive status data from the SIA. For example, controller 170 can comprise a microprocessor, a memory (e.g., volatile and/or non-volatile memory), and a digital I/O port capable of generating control voltages sufficient to communicate and activate inputs to the processing system 100 as well as monitor outputs from the processing system 100. Moreover, the controller 170 can exchange information with chamber 110, upper assembly 120, substrate holder 130, RF system 150, pumping system 160, and SIA 180. Also, a program stored in the memory can be utilized to control the aforementioned components of a material processing system 100 according to a process recipe. In addition, controller 170 can be configured to analyze the status data, to compare the status data with target status data, and to use the comparison to change a process and/or control the processing tool. Also, the controller can be configured to analyze the status data, to compare the status data with historical status data, and to use the comparison to predict, prevent, and/or declare a fault.

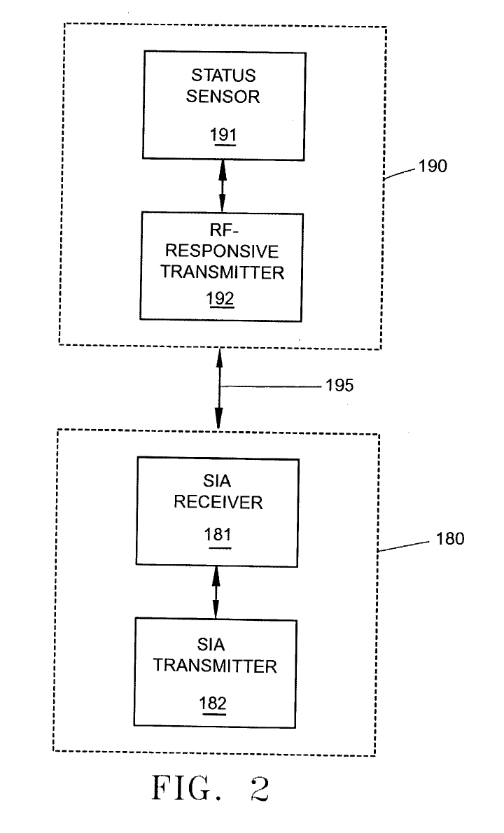

FIG. 2 shows a simplified block diagram of a RF-responsive status sensor and a SIA in accordance with an embodiment of the present invention. In the illustrated embodiment, SIA 180 comprises SIA receiver 181 and SIA transmitter 182, and RF-responsive status sensor 190 comprises status sensor 191 and RF-responsive transmitter 192.

SIA 180 can be coupled to RF-responsive status sensor 190 using communications link 195. For example, RF-responsive status sensor 190 and SIA 180 can operate using one or more RF frequencies in the range from 0.01 MHz to 110.0 GHz. Alternately, communications link 195 can comprise optical means.

SIA receiver 181 can be configured to receive signals from one or more RF-responsive status sensors. For example, SIA receiver 181 can be configured to receive a response signal from at least one RF-responsive status sensor, and the response signal can comprise data, which can include status data.

In addition, SIA transmitter 182 can be configured to transmit signals to one or more RF-responsive status sensors. For example, SIA transmitter 182 can be configured to transmit an input signal to at least one RF-responsive status sensor, and the input signal can comprise data, which can include control data.

Status sensor 191 can be configured to provide one or more component related properties. Status sensor 191 can be configured to generate status data and to provide the status data to a RF-responsive transmitter 192. Status data can comprise at least one of deposition data and erosion data. For example, some system components can have material deposited upon them during system operations and a status sensor 191 can be configured to generate deposition data that can comprise at least one of film thickness data, film uniformity data, and film composition data. In other embodiments, a status sensor 191 can also be configured to generate erosion data. Erosion data can include information for part wear or erosion. In addition, some system components can be eroded during system operations, and a RF-responsive status sensor can be used to monitor the amount of erosion and provide data such as component thickness data, erosion depth data, and component uniformity data. Status data can comprise measured and/or processed data that can be used to control a process, process chamber, and/or processing tool.

In various embodiments, status sensor 191 can comprise at least one of an optical sensor, a micro-electromechanical (MEM) sensor, a surface acoustic wave (SAW) sensor, and a bulk acoustic wave (BAW) sensor. For example, an optical sensor can be a narrowband or wideband device coupled to a system component and can be configured to use one or more optical signals to generate status data. A MEM sensor can be coupled to a system component and can be configured to use one or more MEM resonators to generate status data. A SAW sensor can be coupled to a system component and can be configured to use one or more SAW resonators to generate status data. A BAW sensor can be coupled to a system component and can be configured to use one or more BAW resonators to generate status data. In addition, the sensors can measure, store (e.g., in volatile or non-volatile storage), and/or process status data. Sensors can generate deposition and/or erosion data.

Alternately, status sensor 191 can further comprise at least one of a power source, receiver, transmitter, controller, timer, memory (e.g., volatile and/or non-volatile memory), and a housing.

Status sensor 191 can be configured to generate status data for long periods of time or for short periods of time. For example, a status sensor can comprise at least one of a continuously running timer and a triggered timer, and a triggered timer can be triggered by a process related event or a non-process related event. A status sensor can convert RF energy into a DC signal and use the DC signal to operate the sensor. In this manner, process related data, such as RF hours data, can be generated.

RF-responsive transmitter 192 can be configured to transmit signals to at least one SIA 180. For example, RF-responsive transmitter 192 can be configured to transmit a response signal, and the response signal can comprise data, which can include status data and/or erosion data. Also, the transmitter can be used to process and transmit narrowband and wideband signals including AM signals, FM signals, and/or PM signals. In addition, the transmitter can also process and transmit coded signals and/or spread spectrum signals to increase its performance within a high interference environment such as a semiconductor processing facility.

In various embodiments, RF-responsive transmitter 192 can comprise at least one of a power source, a signal source, a modulator, a coder, an amplifier, an antenna, a memory (e.g., volatile and/or non-volatile memory), a housing, and a controller. In one case, RF-responsive transmitter 192 can comprise an antenna (not shown) that is used as a backscattering device when placed within a RF field.

In alternate embodiments, RF-responsive status sensor 190 can further comprise at least one of a power source, signal source, receiver, antenna, memory (e.g., volatile and/or non-volatile memory), timer, housing, and controller. Also, RF-responsive status sensor 190 can further comprise sensors such as described in co-pending applications 10/______, Attorney Docket No. 231748US6YA, filed on even date herewith, entitled “Method and Apparatus for Monitoring a Material Processing System”; 10/______, Attorney Docket No. 231750US6YA, filed on even date herewith, entitled “Method and Apparatus for Monitoring a Material Processing System”; 10/______, Attorney Docket No. 231227US6YA, filed on even date herewith, entitled “Method and Apparatus for Monitoring Parts in a Material Processing System”; and 10/______, Attorney Docket No. 231228US6YA, filed on even date herewith, entitled “Method and Apparatus for Monitoring a Plasma in a Material Processing System”, all of which are incorporated by reference herein.

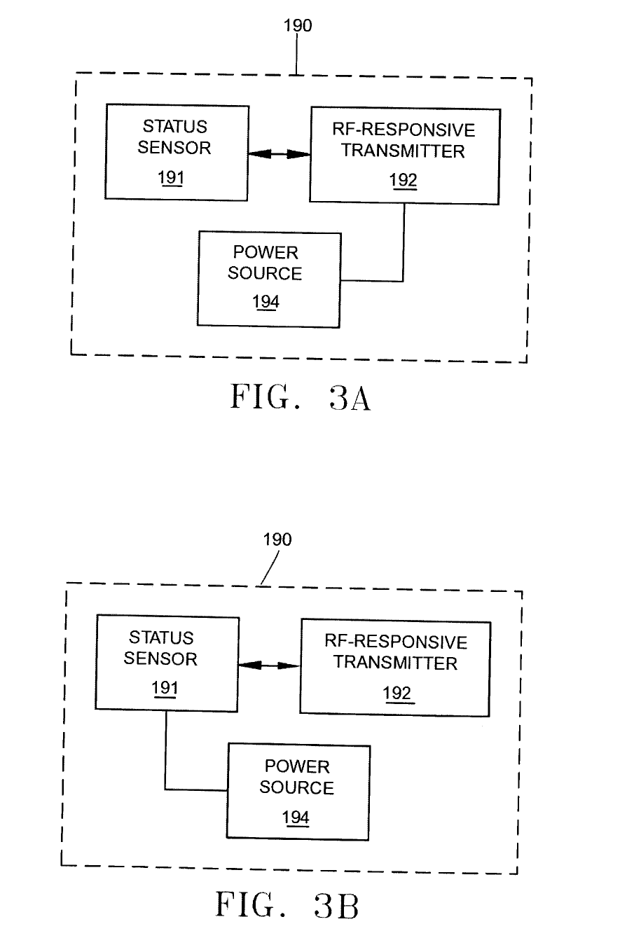

FIGS. 3a -3c show simplified block diagrams of a RF-responsive status sensor in accordance with embodiments of the present invention. In the illustrated embodiments, RF-responsive status sensor 190 comprises status sensor 191, RF-responsive transmitter 192, and power source 194.

As shown in FIG. 3a, power source 194 can be coupled to RF-responsive transmitter 192. Alternately, power source 194 can be incorporated within RF-responsive transmitter 192. As shown in FIG. 3b, power source 194 can be coupled to status sensor 191. Alternately, power source 194 can be incorporated within status sensor 191. As shown in FIG. 3c, power source 194 can be coupled to status sensor 191 and RF-responsive transmitter 192. Alternately, power source 194 can be incorporated within status sensor 191 and within RF-responsive transmitter 192.

Power source 194 can comprise at least one of a RF-to-DC converter, a DC-to-DC converter, and a battery. For example, RF-to-DC converter can comprise at least one of an antenna, diode, and filter. In one case, a RF-to-DC converter can convert at least one process related frequency into a DC signal. In another case, a RF-to-DC converter can convert at least one non-process related frequency into a DC signal. For instance, an external signal can be provided to the converter. Alternately, a RF-to-DC converter can convert at least one plasma related frequency into a DC signal.

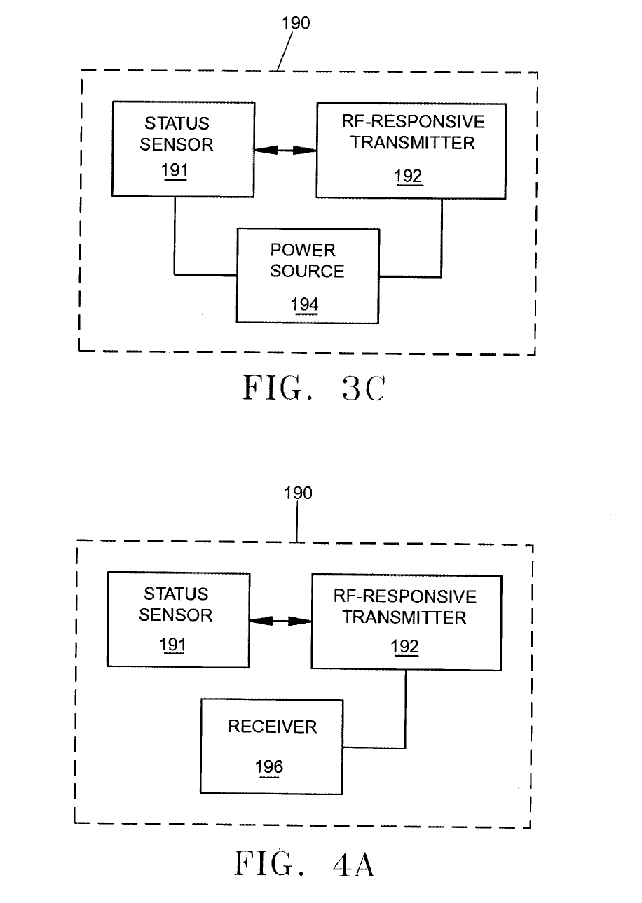

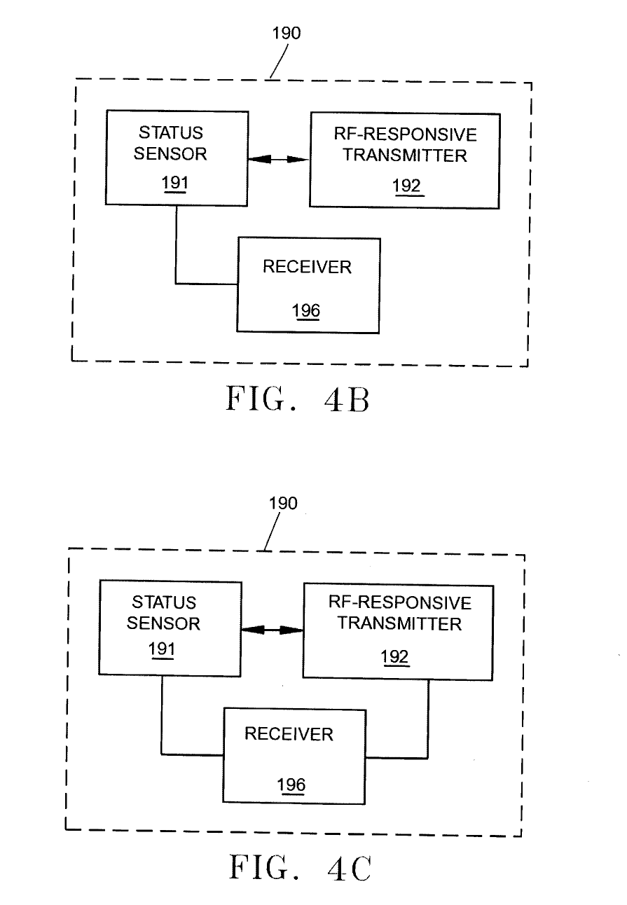

FIGS. 4a-4c show simplified block diagrams of a RF-responsive status sensor in accordance with additional embodiments of the present invention. In the illustrated embodiments, RF-responsive status sensor 190 comprises status sensor 191, RF-responsive transmitter 192, and receiver 196.

As shown in FIG. 4a, receiver 196 can be coupled to RF-responsive transmitter 192. Alternately, receiver 196 can be incorporated within RF-responsive transmitter 192. As shown in FIG. 4b, receiver 196 can be coupled to status sensor 191. Alternately, receiver 196 can be incorporated within status sensor 191. As shown in FIG. 4c, receiver 196 can be coupled to status sensor 191 and RF-responsive transmitter 192. Alternately, receiver 196 can be incorporated within status sensor 191 and within RF-responsive transmitter 192.

Receiver 196 can comprise at least one of a power source, signal source, antenna, down converter, demodulator, decoder, controller, memory (e.g., volatile and/or non-volatile memory), and converters. For example, the receiver can be used to receive and process narrowband and wideband signals including AM signals, FM signals, and/or PM signals. In addition, the receiver can also receive and process coded signals and/or spread spectrum signals to increase its performance within a high interference environment such as a semiconductor processing facility.

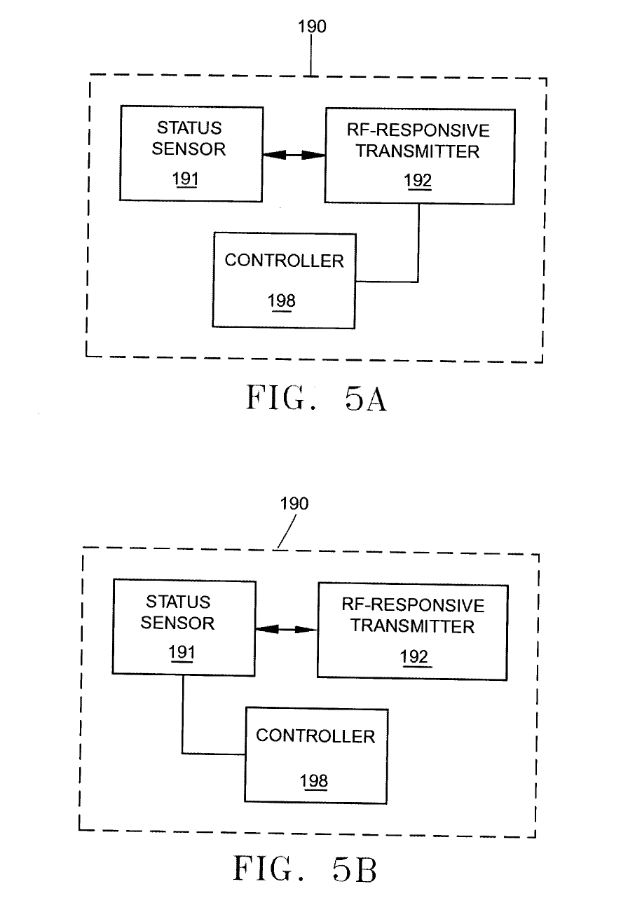

FIGS. 5a-5c show simplified block diagrams of a RF-responsive status sensor in accordance with additional embodiments of the present invention. In the illustrated embodiments, RF-responsive status sensor 190 comprises status sensor 191, RF-responsive transmitter 192, and controller 198.

As shown in FIG. 5a, controller 198 can be coupled to RF-responsive transmitter 192. Alternately, controller 198 can be incorporated within RF-responsive transmitter 192. As shown in FIG. 5b, controller 198 can be coupled to status sensor 191. Alternately, controller 198 can be incorporated within status sensor 191. As shown in FIG. 5c, controller 198 can be coupled to status sensor 191 and RF-responsive transmitter 192. Alternately, controller 198 can be incorporated within status sensor 191 and within RF-responsive transmitter 192.

Controller 198 can comprise at least one of a microprocessor, microcontroller, timer, digital signal processor (DSP), memory (e.g., volatile and/or non-volatile memory), A/D converter, and D/A converter. For example, the controller can be used to process data received from AM signals, FM signals, and/or PM signals and can be used to process data to be transmitted on AM signals, FM signals, and/or PM signals. In addition, controller 198 can be used to process coded and/or spread spectrum signals. Also, controller 198 can be used to store information such as measured data, instructional code, sensor information, and/or part information, which can include sensor identification and part identification data. For instance, input signal data can be provided to controller 198.

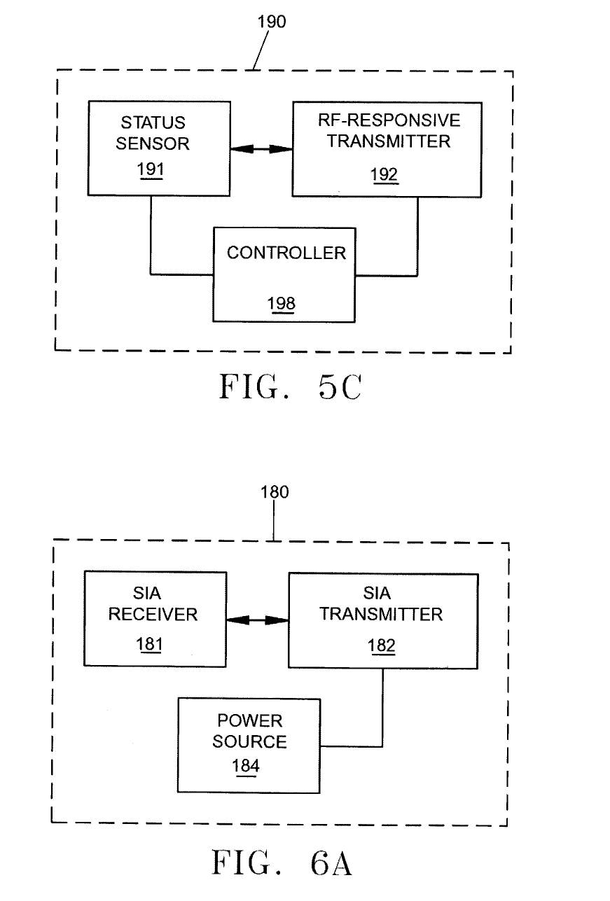

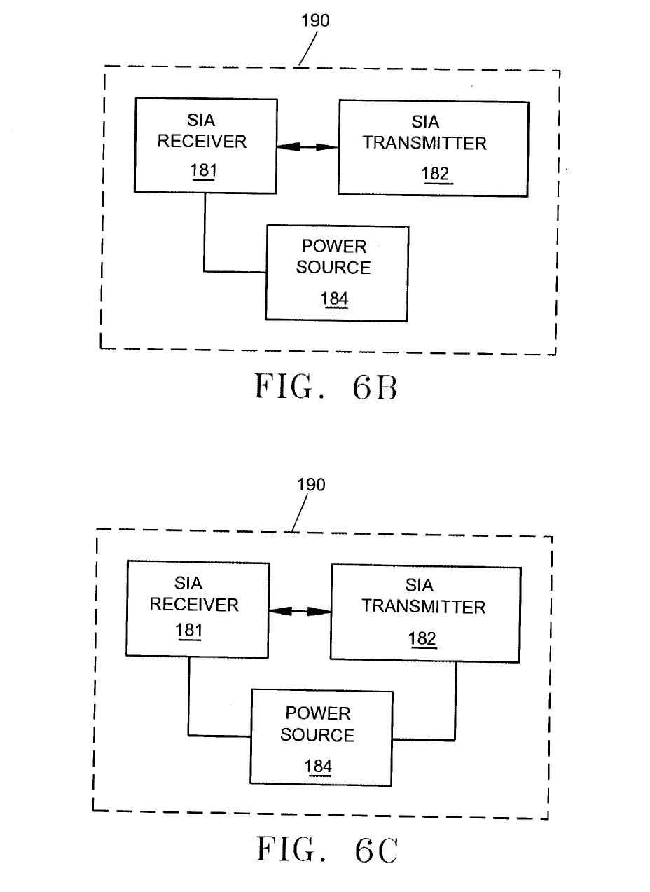

FIGS. 6a-6c show simplified block diagrams of a SIA in accordance with embodiments of the present invention. In the illustrated embodiments, SIA 180 comprises SIA receiver 181, SIA transmitter 182, and power source 184.

SIA transmitter 182 can be configured to transmit an input signal to at least one RF-responsive status sensor, and the at least one RF-responsive status sensor can use the input signal to control its operation. For example, a RF-responsive status sensor can use the input signal information to determine when to generate status data and/or when to transmit a response signal.

SIA transmitter 182 can comprise at least one of a power source, signal source, antenna, up converter, amplifier, modulator, coder, timer, controller, memory (e.g., volatile and/or non-volatile memory), a D/A converter, and an A/D converter. For example, the transmitter can be used to process and transmit narrowband and wideband signals including AM signals, FM signals, and/or PM signals. In addition, SIA transmitter 182 can be configured to process and transmit coded signals and/or spread spectrum signals to increase performance within a high interference environment such as a semiconductor processing facility.

SIA receiver 181 can be configured to receive a response signal from at least one RF-responsive status sensor, and the response signal can comprise status data.

SIA receiver 181 can comprise at least one of a power source, a signal source, antenna, down converter, demodulator, decoder, timer, controller, memory (e.g., volatile and/or non-volatile memory), a D/A converter, and an A/D converter. For example, the SIA receiver can be used to receive and process narrowband and wideband signals including AM signals, FM signals, and/or PM signals. In addition, SIA receiver 181 can also be configured to receive and process coded signals and/or spread spectrum signals to increase performance within a high interference environment such as a semiconductor processing facility.

As shown in FIG. 6a, power source 184 can be coupled to SIA transmitter 182. Alternately, power source 184 can be incorporated within SIA transmitter 182. As shown in FIG. 6b, power source 184 can be coupled to SIA receiver 181. Alternately, power source 184 can be incorporated within SIA receiver 182. As shown in FIG. 6c, power source 184 can be coupled to SIA receiver 181 and SIA transmitter 182. Alternately, power source 184 can be incorporated within SIA receiver 181 and SIA transmitter 182.

Power source 184 can comprise at least one of a RF-to-DC converter, DC-to-DC converter, a battery, filter, timer, memory (e.g., volatile and/or non-volatile memory), and a controller. In addition, the power source can be external to the chamber and coupled to the SIA using one or more cables.

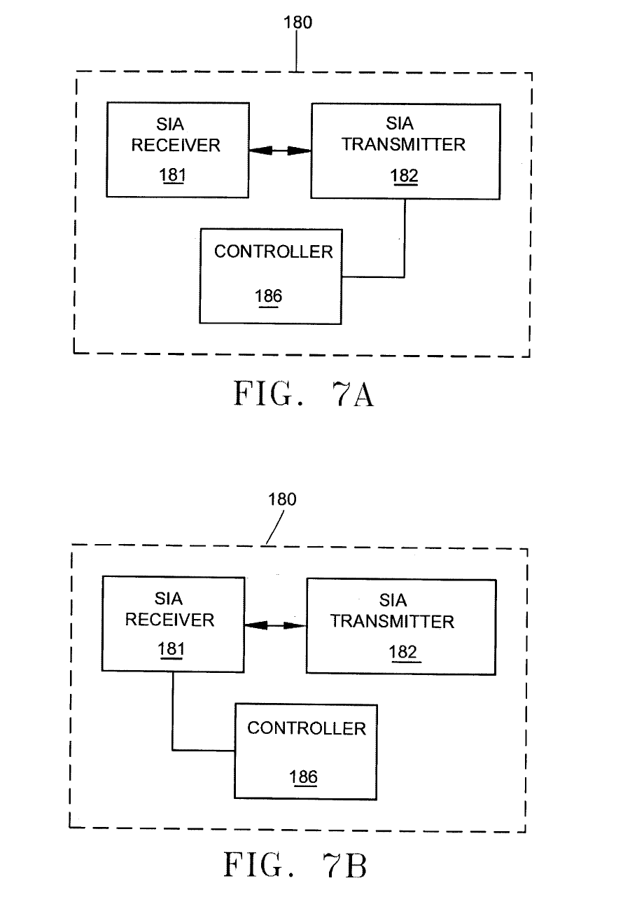

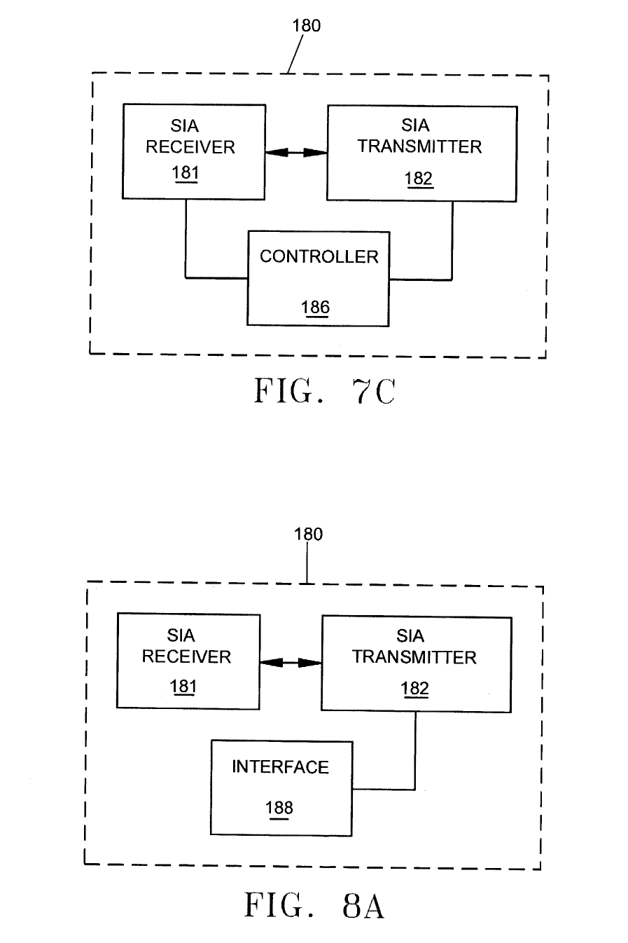

FIGS. 7a-7c show simplified block diagrams of a sensor interface assembly in accordance with additional embodiments of the present invention. In the illustrated embodiments, SIA 180 comprises SIA receiver 181, SIA transmitter 182, and controller 186.

As shown in FIG. 7a, controller 186 can be coupled to SIA receiver 181. Alternately, controller 186 can be incorporated within SIA receiver 181. As shown in FIG. 7b, controller 186 can be coupled to SIA transmitter 182. Alternately, controller 186 can be incorporated within SIA transmitter 182. As shown in FIG. 7c, controller 186 can be coupled to SIA receiver 181 and SIA transmitter 182. Alternately, controller 186 can be incorporated within SIA receiver 181 and SIA transmitter 182.

Controller 186 can comprise at least one of a microprocessor, microcontroller, digital signal processor (DSP), memory (e.g., volatile and/or non-volatile memory), A/D converter, and D/A converter. For example, the controller can be used to process data received from response signals and can be used to process data to be transmitted on input signals. Also, controller 186 can be used to store information such as measured data, instructional code, sensor information, and/or part information, which can include sensor identification and part identification data.

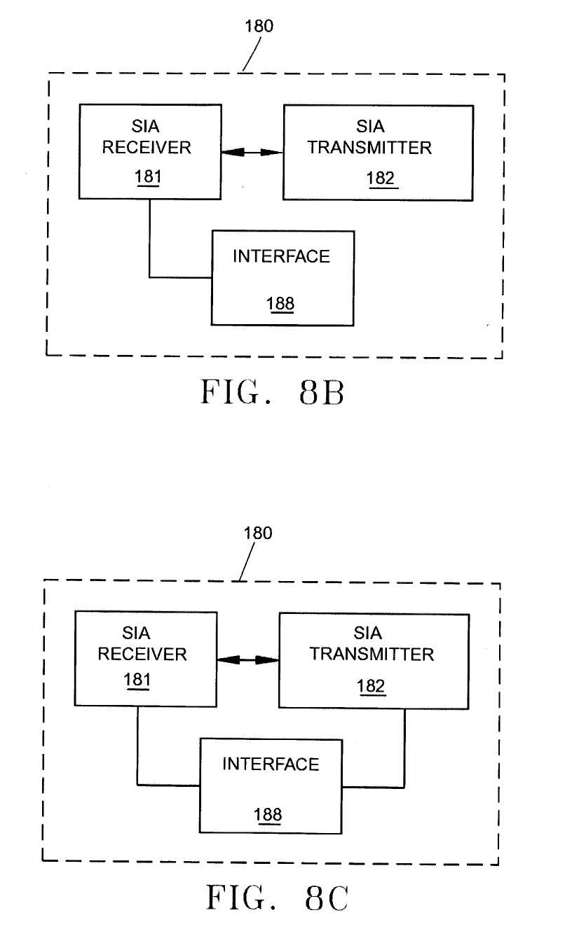

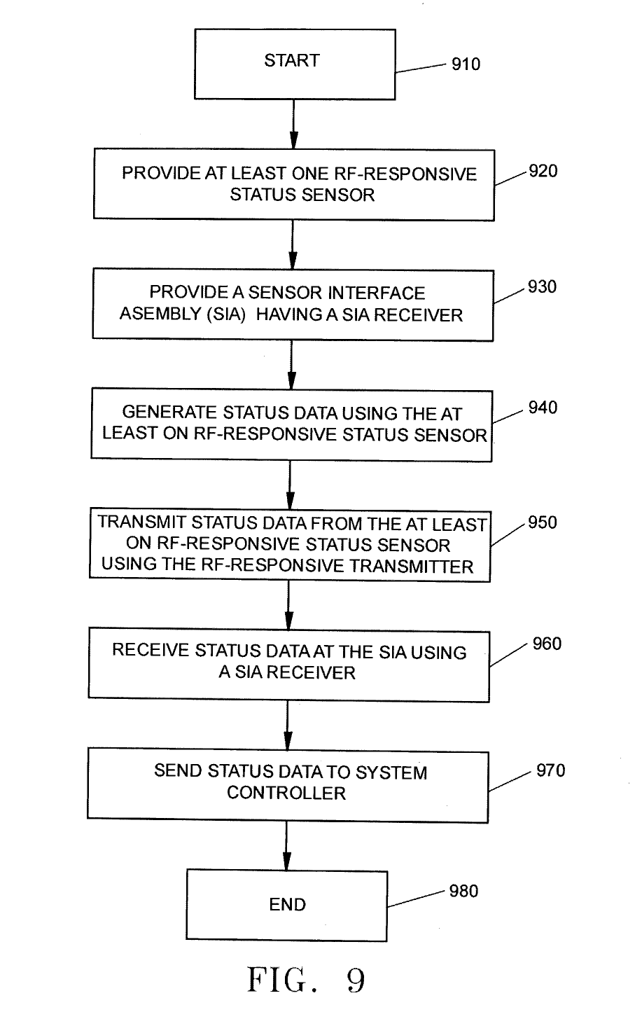

FIGS. 8a-8c show simplified block diagrams of a sensor interface assembly in accordance with additional embodiments of the present invention. In the illustrated embodiments, SIA 180 comprises SIA receiver 181, SIA transmitter 182, and interface 188.

As shown in FIG. 8a, interface 188 can be coupled to SIA receiver 181. Alternately, interface 188 can be incorporated within SIA receiver 181. As shown in FIG. 8b, interface 188 can be coupled to SIA transmitter 182. Alternately, interface 188 can be incorporated within SIA transmitter 182. As shown in FIG. 8c, interface 188 can be coupled to SIA receiver 181 and SIA transmitter 182. Alternately, interface 188 can be incorporated within SIA receiver 181 and SIA transmitter 182.

Interface 188 can comprise at least one of a power source, a signal source, a receiver, a transmitter, a controller, a processor, memory (e.g., volatile and/or non-volatile memory), a timer, and a converter. For example, the interface can be used to process data received from and sent to a system level component, such as controller 170 (FIG. 1).

Those skilled in the art will recognize that a receiver and transmitter can be combined into a transceiver.

FIG. 9 illustrates a method for monitoring a material processing system according to an embodiment of the present invention. Procedure 900 begins in 910.

In 920, at least one RF-responsive status sensor is provided. RF-responsive status sensors can be provided in a number of different locations in a material processing system. For example, RF-responsive status sensors can be coupled to chamber components, upper assembly components, and substrate holder components. Also, RF-responsive status sensors can be coupled to a chamber liner (process tube) when one is used in the material processing system. In addition, RF-responsive status sensors can be coupled to a transfer system component, a RF system component, a gas supply system component, and/or an exhaust system component when one or more of these components are used in the material processing system.

A RF-responsive status sensor can comprise an RF-responsive transmitter coupled to an status sensor. In various embodiments, status sensor can comprise at least one of an antenna, voltage probe, current probe, voltage/current (V/I) probe, field probe, Langmuir probe, memory (e.g., volatile and/or non-volatile memory), processor, timer, and a housing. For example, an antenna and/or a probe can be used to measure electrical signals in a process chamber, and/or outside of a process chamber. Probes can be coupled to components that are used to provide RF signals to a process chamber and/or processing tool.

A status sensor can be configured to generate data, such as status data, and provide the data to an RF-responsive transmitter. Also, a status sensor can comprise at least one of a processor, memory (e.g., volatile and/or non-volatile memory), timer, and power source, and an status sensor to generate, store, and/or process data, such as status data, using internal control procedures and then provide the data to an RF-responsive transmitter. A status sensor can use a process related and/or non-process related signal to determine when to operate. Alternately, a status sensor can further comprise at least one of a receiver, transmitter, and housing.

In various embodiments, a RF-responsive transmitter comprises a transmitter and an antenna. For example, the transmitter can be configured to modulate and/or encode an input signal with data, such as the status data, and the antenna can be configured to transmit the input signal.

In other cases, an RF-responsive transmitter can comprise a modulator and an antenna, and the modulator can be configured to modulate an input signal with the status data and the antenna can be configured to transmit the modulated signal. Alternately, a RF-responsive transmitter can comprise an antenna and a backscatter modulator.

In 930, a sensor interface assembly (SIA) is provided. A SIA can be provided in a number of different locations in a material processing system. For example, a SIA can be coupled to a chamber, upper assembly, and substrate holder. In other embodiments, a SIA can be installed outside a chamber if a communication link can be established with a RF-responsive status sensor. Alternately, SIA can be coupled to a monitoring port or another input port.

A SIA can comprise a receiver configured to receive a response signal from at least one RF-responsive status sensor, and the response signal can comprise data, such as status data. For example, a RF-responsive status sensor can be configured to generate and transmit a response signal using internal control procedures that can be process dependent and/or process independent.

In addition, the SIA can comprise a transmitter configured to transmit an input signal to at least one RF-responsive status sensor, and the input signal can comprise operational data for the at least one RF-responsive status sensor. For example, a RF-responsive status sensor can be configured to generate and transmit a response signal when it receives an input signal from a SIA.

In other cases, the SIA can comprise a power source that can be coupled to the SIA transmitter and SIA receiver. In other embodiments, the SIA can comprise a controller that can be coupled to the SIA transmitter and SIA receiver.

In 940, a RF-responsive status sensor having a status sensor and a RF-responsive transmitter can be used to generate data, such as status data. A status sensor can generate status data before, during, and after a process. For example, RF-responsive status sensors can generate status data for chamber components, upper assembly components, and substrate holder components. In addition, a RF-responsive status sensor can generate status data for a chamber liner (process tube) when one is used in the material processing system. Furthermore, a RF-responsive status sensor can generate status data for transfer system component, a RF system component, a gas supply system component, and/or an exhaust system component.

A RF-responsive status sensor can be configured to provide one or more component related properties. For example, a status sensor can be configured to generate status data that can comprise at least one of deposition data and erosion data. For example, deposition data can comprise at least one of film thickness data, film uniformity data, and film composition data. Erosion data can comprise at least one of component thickness data, erosion depth data, and component uniformity data. Status data can comprise measured and/or processed data that can be used to control a process, process chamber, and/or processing tool. Status data can also be used in installation, operational, and/or maintenance procedures. Status data can include measurements taken before, during, and/or after a process. Alternately, status data can include measurements taken before, during, and/or after a plasma process.

In one or more embodiments, a RF-responsive status sensor can comprise a power source and the power source can be configured to use a process related frequency to cause the RF-responsive status sensor to generate status data. For example, the power source can convert some of the RF energy provided to a process chamber into a DC signal and use the DC signal to operate the status sensor in the RF-responsive status sensor. Alternately, the RF-responsive status sensor can comprise a battery coupled to the status sensor, and the DC signal can be used to cause the status sensor to begin generating status data.

In other embodiments, a RF-responsive status sensor can comprise a power source and the power source can be configured to use a non-plasma related frequency to cause the RF-responsive status sensor to generate status data. For example, the power source can convert some of the RF energy provided by an input signal into a DC signal and use the DC signal to operate the status sensor in the RF-responsive status sensor. Alternately, the RF-responsive status sensor can comprise a battery coupled to the status sensor, and the input signal can be used to cause the status sensor to begin generating status data.

In additional embodiments, a RF-responsive status sensor can be used in a plasma processing system and can be configured to use plasma related and non-plasma related frequencies to generate data such as status data.

In 950, at least one RF-responsive status sensor uses its RF-responsive transmitter to transmit the status data. For example, a RF-responsive transmitter can transmit a response signal that includes data such as the status data. In an alternate embodiment, a RF-responsive transmitter can be coupled to more than one status sensor, and a RF-responsive transmitter can be coupled to one or more additional sensors.

A RF-responsive status sensor can be provided in a number of different locations in a material processing system and can be configured to transmit status data before, during, and/or after a plasma process is performed by the material processing system. For example, RF-responsive status sensors can be coupled to at least one of a chamber component, an upper assembly component, and a substrate holder component and can transmit status data from different locations in the system. In addition, a RF-responsive status sensor can transmit status data from a chamber liner (process tube) when one is used in the material processing system. Furthermore, a RF-responsive status sensor can transmit status data from a transfer system component, a RF system component, a gas supply system component, and/or an exhaust system component.

In some embodiments, a RF-responsive status sensor can comprise a power source, and the power source can be configured to use a plasma related frequency to cause the RF-responsive status sensor to transmit status data. For example, the power source can convert some of the RF energy provided to the process chamber into a DC signal and use the DC signal to operate the transmitter in the RF-responsive status sensor. Also, the RF-responsive status sensor can comprise a battery coupled to the transmitter and can use a process related signal to cause the RF-responsive transmitter to begin transmitting data.

In other embodiments, a RF-responsive status sensor can comprise a power source and the power source can be configured to use a non-process related frequency to cause the RF-responsive status sensor to transmit status data. For example, the power source can convert some of the RF energy provided by an input signal into a DC signal and use the DC signal to operate the transmitter in the RF-responsive status sensor. Also, the RF-responsive status sensor can comprise a battery coupled to the transmitter and can use the input signal to cause the RF-responsive transmitter to begin transmitting data.

Furthermore, the RF-responsive status sensor be used in a plasma processing system and can be configured to transmit a response signal using a plasma related frequency or a non-plasma related frequency when transmitting data such as status data.

In alternate embodiments, a RF-responsive status sensor can comprise a receiver that can be used to receive an input signal. For example, a receiver can be configured to receive an input signal and to use the input signal to generate operational data for controlling the RF-responsive status sensor. Also, the RF-responsive status sensor can use the input signal to determine when to generate data and/or when to transmit data.

In other embodiments, a RF-responsive status sensor can comprise a memory that can be used to store data such as status data. Status data can be stored during part of a process and transmitted during a different part of the process. For example, status data can be stored during a plasma event and transmitted after the plasma event has ended.

In other embodiments, a RF-responsive status sensor can comprise a controller that can be used to control the operation of the RF-responsive status sensor. The controller can comprise operational data and/or receive operational data from an SIA. For example, the controller can be used to determine when to generate and transmit the status data.

In some embodiments, a RF-responsive status sensor can comprise a timer. Timer can comprise at least one of a continuously running timer and a triggered timer, and a triggered timer can be triggered by a process related or a non-process related frequency. For example, a timer can convert RF energy into a DC signal and use the DC signal to operate the timer. In this manner, RF hour data can be generated. Also, a timer can be triggered by an input signal received by the RF-responsive status sensor.

In 960, a SIA can be used to receive a response signal from one or more RF-responsive status sensors, and the response signal can comprise data such as status data. For example, the receiver in the SIA can be configured to receive one or more response signals during an entire process or during part of a process. In some cases, a RF-responsive status sensor can transmit status data when a RF signal is provided to a process chamber.

In addition, a SIA can be used to transmit an input signal to one or more RF-responsive status sensors. For example, the transmitter in the SIA can be configured to transmit one or more input signals during an entire process or during part of a process. In some cases, a RF-responsive status sensor can transmit status data to a SIA when it receives an input signal from the SIA. An input signal, for example, can comprise operational data for the RF-responsive status sensor.

The SIA can use internal and/or external control data to determine when to receive and when to transmit signals. For example, a SIA can be configured to operate before, during, and/or after a process is performed by the material processing system

A SIA can be provided at one or more locations in a material processing system. For example, a SIA can be coupled to at least one of a chamber wall, an upper assembly, and a substrate holder and can receive status data from different locations in the system. In addition, a SIA can receive status data from a RF-responsive status sensor coupled to a chamber liner (process tube) when one is used in the material processing system. Furthermore, a SIA can receive status data from a RF-responsive status sensor coupled to a transfer system component, a RF system component, a gas supply system component, and/or an exhaust system component.

In some embodiments, a SIA can comprise a power source and the power source can be configured to use a plasma related frequency to cause the SIA to operate. For example, the power source can comprise a RF-to-DC converter that can convert some of the RF energy provided to the plasma chamber into a DC signal, and the DC signal can be used to operate the transmitter and/or receiver in the SIA.

In other embodiments, a SIA can comprise a power source and the power source can be configured to use a non-plasma related frequency to cause the SIA to operate. For example, the power source can comprise a RF-to-DC converter that can convert some of the RF energy provided by an external signal into a DC signal, and the DC signal can be used to operate the transmitter and/or receiver in the SIA.

In addition, the power source can be external to the chamber and coupled to the SIA using one or more cables. Also, the power source can comprise a battery.

If SIA 180 does not receive a response from an RF-responsive status sensor 190 (1) after sending the sensor 190 a request message and/or (2) after a time specified by the timer of the sensor 190, the system may indicate an error status (e.g., to an operator) such that the equipment corresponding to the non-responsive sensor may be checked. Operation of the system may need to be halted in such a case.

In 970, the SIA can send data, such as status data, to a controller. In addition, the SIA can preprocess the status data. For example, the SIA can compress and/or encrypt the data. Procedure 900 ends in 980.

The SIA and/or a system controller can be configured to analyze data such as the status data and to use the analysis results to control a process and/or control a processing tool. The SIA and/or a system controller can be configured to compare the status data with target status data, and to use the comparison to control a process and/or control a processing tool. Also, the SIA and/or a system controller can be configured to compare the status data with historical status data, and to use the comparison to predict, prevent, and/or declare a fault. Furthermore, the SIA and/or a system controller can be configured to analyze data such as the status data and to use the analysis results to determine when to perform maintenance on a component. Moreover, the status data of one component or sensor (or a processed version thereof) may be transmitted back to another component or sensor so that the corresponding equipment of the receiving sensor can know and/or remember the environment(s) in which it has been used.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A material processing system comprising:
a processing tool, wherein the processing tool includes at least one process chamber;
a plurality of RF-responsive status sensors coupled to the processing tool, a RF-responsive status sensor being configured to generate status data for the processing tool and transmit the status data; and
a sensor interface assembly (SIA) configured to receive the status data from at least one RF-responsive status sensor.

2. The material processing system as claimed in claim 1, wherein the status data comprises at least one of deposition data and erosion data.

3. The material processing system as claimed in claim 2, wherein the status data comprises at least one of film thickness data, film uniformity data, and film composition data.

4. The material processing system as claimed in claim 2, wherein the status data comprises at least one of component thickness data, component uniformity data, and component composition data.

5. The material processing system as claimed in claim 1, wherein at least one RF-responsive status sensor comprises:
a status sensor for generating the status data; and
a RF-responsive transmitter coupled to the status sensor for transmitting the status data.

6. The material processing system as claimed in claim 5, wherein the process sensor comprises at least one of an optical sensor, a micro-electromechanical (MEM) sensor, a surface acoustic wave (SAW) sensor, and a bulk acoustic wave (BAW) sensor.

7. The material processing system as claimed in claim 1, wherein at least one RF-responsive status sensor is coupled to a chamber component.

8. The material processing system as claimed in claim 7, wherein the at least one RF-responsive status sensor comprises:
a status sensor configured to generate status data for the chamber component; and
a RF-responsive transmitter coupled to the status sensor for transmitting the status data for the chamber component.

9. The material processing system as claimed in claim 1, further comprising an upper assembly, wherein at least one RF-responsive electrical sensor is coupled to at least one component of the upper assembly.

10. The material processing system as claimed in claim 9, wherein the at least one RF-responsive electrical sensor comprises:
an electrical sensor configured to generate electrical data for the at least one component of the upper assembly; and
a RF-responsive transmitter coupled to the electrical sensor for transmitting the electrical data for the at least one component of the upper assembly.

11. The material processing system as claimed in claim 1, further comprising a substrate holder, wherein at least one RF-responsive status sensor is coupled to the substrate holder.

12. The material processing system as claimed in claim 11, wherein the substrate holder comprises at least one of a chuck, an electrostatic chuck (ESC), a shield, a focus ring, a baffle, and an electrode.

13. The material processing system as claimed in claim 11, wherein the at least one RF-responsive status sensor comprises:
a status sensor configured to generate status data for the substrate holder; and
a RF-responsive transmitter coupled to the status sensor for transmitting the status data for the substrate holder.

14. The material processing system as claimed in claim 11, wherein the at least one RF-responsive status sensor comprises:
a status sensor configured to generate status data for a wafer on the substrate holder; and
a RF-responsive transmitter coupled to the status sensor for transmitting the status data for the wafer.

15. The material processing system as claimed in claim 1, further comprising a ring, wherein at least one RF-responsive status sensor is coupled to the ring.

16. The material processing system as claimed in claim 15, wherein the ring comprises at least one of a focus ring, a shield ring, a deposition ring, an electrode ring, and an insulator ring.

17. The material processing system as claimed in claim 15, wherein the at least one RF-responsive status sensor comprises:
an status sensor configured to generate status data for the ring; and
a RF-responsive transmitter coupled to the status sensor for transmitting the status data for the ring.

18. The material processing system as claimed in claim 1, further comprising a plate, wherein at least one RF-responsive status sensor is coupled to the plate.

19. The material processing system as claimed in claim 18, wherein the plate comprises at least one of an exhaust plate, a baffle plate, an electrode plate, and an insulator plate.

20. The material processing system as claimed in claim 18, wherein the at least one RF-responsive status sensor comprises:
a status sensor configured to generate status data for the plate; and
a RF-responsive transmitter coupled to the status sensor for transmitting the status data for the plate.

21. The material processing system as claimed in claim 5, wherein the at least one RF-responsive status sensor further comprises a timer coupled to at least one of the status sensor and the RF-responsive transmitter.

22. The material processing system as claimed in claim 5, wherein the RF-responsive transmitter comprises an antenna configured to transmit a response signal, and a transmitter coupled to the antenna, wherein the transmitter is configured to modulate and/or encode the response signal with the status data.

23. The material processing system as claimed in claim 5, wherein the RF-responsive status sensor further comprises a power source coupled to at least one of the status sensor and the RF-responsive transmitter

24. The material processing system as claimed in claim 23, wherein the power source comprises at least one of a RF-to-DC converter configured to convert energy emitted from a process related signal into a DC signal, a RF-to-DC converter configured to convert a non-process related signal into a DC signal, a DC-to-DC converter, and a battery.

25. The material processing system as claimed in claim 24, wherein the power source provides the DC signal to the status sensor.

26. The material processing system as claimed in claim 24, wherein the power source provides the DC signal to the RF-responsive transmitter.

27. The material processing system as claimed in claim 5, wherein the at least one RF-responsive status sensor further comprises a controller coupled to at least one of the status sensor and the RF-responsive transmitter.

28. The material processing system as claimed in claim 27, wherein the controller comprises at least one of a microprocessor, a microcontroller, a timer, digital signal processor (DSP), memory, receiver, A/D converter, and D/A converter

29. The material processing system as claimed in claim 1, wherein at least one RF-responsive status sensor comprises:
a status sensor for generating status data;
a RF-responsive transmitter coupled to the status sensor for transmitting the status data; and
a receiver coupled to at least one of the status sensor and the RF-responsive transmitter.

30. The material processing system as claimed in claim 29, wherein the RF-responsive transmitter comprises an antenna and a backscatter modulator.

31. The material processing system as claimed in claim 29, wherein the RF-responsive transmitter comprises an antenna configured to transmit a response signal, and a transmitter coupled to the antenna, wherein the transmitter is configured to modulate and/or encode the response signal with the status data.

32. The material processing system as claimed in claim 31, wherein the RF-responsive transmitter further comprises at least one of a RF-to-DC converter, a DC-to-DC converter, and a battery.

33. The material processing system as claimed in claim 29, wherein the RF-responsive status sensor further comprises at least one power source, a power source producing a DC signal using at least one of a RF-to-DC converter, a DC-to-DC converter, and a battery.

34. The material processing system as claimed in claim 29, wherein the receiver comprises an antenna and processor, the antenna being configured to receive an input signal, the processor being configured to use the input signal to generate operational data, and to use the operational data to control at least one of the RF-responsive transmitter, the receiver, and the status sensor.

35. The material processing system as claimed in claim 34, wherein the receiver further comprises at least one of a RF-to-DC converter configured to convert energy emitted from a process related signal into a DC signal, a RF-to-DC converter configured to convert a non-process related signal into a DC signal, a DC-to-DC converter, and a battery.

36. The material processing system as claimed in claim 29, wherein the at least one RF-responsive status sensor further comprises a controller coupled to at least one of the receiver, the status sensor, and the RF-responsive transmitter.

37. The material processing system as claimed in claim 36, wherein the controller comprises at least one of a microprocessor, a microcontroller, a timer, digital signal processor (DSP), memory, A/D converter, and D/A converter

38. The material processing system as claimed in claim 1, wherein at least one RF-responsive status sensor comprises:
a status sensor for generating status data; and
a RF-responsive transceiver coupled to the status sensor for transmitting the status data.

39. The material processing system as claimed in claim 38, wherein the RF-responsive transceiver comprises an antenna configured to transmit a response signal, a transmitter coupled to the antenna, wherein the transmitter is configured to modulate and/or encode the response signal with the status data, a second antenna, receiver, and processor, the second antenna being configured to receive an input signal, the receiver being configured to use the input signal to generate operational data, the processor being configured to use the operational data to control the RF-responsive transceiver.

40. The material processing system as claimed in claim 38, wherein the at least one RF-responsive status sensor further comprises a controller coupled to at least one of the status sensor and the RF-responsive transceiver.

41. The material processing system as claimed in claim 40, wherein the controller comprises at least one of a microprocessor, a microcontroller, a timer, digital signal processor (DSP), timer, memory, A/D converter, and D/A converter.

42. The material processing system as claimed in claim 38, wherein the at least one RF-responsive status sensor further comprises at least one power source coupled to at least one of the status sensor and the RF-responsive transceiver, a power source comprising at least one of a RF-to-DC converter, a DC-to-DC converter, and a battery.

43. The material processing system as claimed in claim 1, wherein the SIA comprises:
a receiver configured to receive a response signal containing the status data from at least one RF-responsive status sensor; and
a transmitter configured to transmit an input signal to the at least one RF-responsive status sensor, wherein the input signal causes the at least one RF-responsive status sensor to send the response signal to the receiver.

44. The material processing system as claimed in claim 1, wherein the material processing system further comprises:
a controller coupled to the SIA, the controller being configured to analyze the status data, wherein the controller compares the status data with target electrical performance data, and to use the comparison to change a process.

45. The material processing system as claimed in claim 1, wherein the material processing system further comprises:
a controller coupled to the SIA, the controller being configured to analyze the status data, wherein the controller compares the status data with historical status data, and to use the comparison to predict a fault.

46. The material processing system as claimed in claim 1, wherein the material processing system further comprises:
a controller coupled to the SIA, the controller being configured to analyze the status data, wherein the controller compares the status data with historical status data, and to use the comparison to declare a fault.

47. The material processing system as claimed in claim 1, wherein the material processing system further comprises:
a controller coupled to the SIA, the controller being configured to provide instructional data to the SIA.

48. The material processing system as claimed in claim 1, wherein the material processing system further comprises:
a controller coupled to the SIA, the controller being configured to analyze the status data and control the processing tool.

49. The material processing system as claimed in claim 1, further comprising a RF system, wherein a RF-responsive status sensor is coupled to at least one RF system component.

50. The material processing system as claimed in claim 1, further comprising a gas supply system, wherein a RF-responsive status sensor is coupled to at least one gas supply system component.

51. The material processing system as claimed in claim 1, further comprising a transfer system, wherein a RF-responsive status sensor is coupled to at least one transfer system component.

52. The material processing system as claimed in claim 1, further comprising an exhaust system, wherein a RF-responsive status sensor is coupled to at least one exhaust system component.

53. The material processing system as claimed in claim 1, wherein the material processing system further comprises:
a controller coupled to the SIA, the controller being configured to analyze the status data and to use the analysis results to determine when to perform maintenance on the processing tool.

54. A RF-responsive status sensor comprising:
a status sensor configured to generate status data for a component in a material processing system; and
a RF-responsive transmitter coupled to the status sensor for transmitting the status data for the component.

55. The RF-responsive status sensor as claimed in claim 54, wherein the component is part of an etching system.

56. The RF-responsive status sensor as claimed in claim 54, wherein the component is part of a deposition system.

57. The RF-responsive status sensor as claimed in claim 54, wherein the component is part of a cleaning system.

58. The RF-responsive status sensor as claimed in claim 54, wherein the component is part of a transfer system.

59. A plasma processing system comprising:
a processing tool, wherein the processing tool includes a plasma chamber;
a plurality of RF-responsive status sensors coupled to the processing tool to generate and transmit status data, wherein at least one RF-responsive status sensor is coupled to the plasma chamber; and
a sensor interface assembly (SIA) configured to receive the status data from the plurality of RF-responsive status sensors.

60. The material processing system as claimed in claim 59, wherein the processing system further comprises:
a controller coupled to the SIA, the controller being configured to analyze the status data and control the plasma processing system.

61. A method of monitoring a material processing system comprising a processing tool, wherein the processing tool includes at least one process chamber, the method comprising:
providing a RF-responsive status sensor coupled to the processing tool, wherein the RF-responsive status sensor is configured to generate and transmit status data; and
providing a sensor interface assembly (SIA), wherein the SIA is configured to receive the status data from the RF-responsive status sensor.

62. The method of monitoring a material processing system as claim in claim 61, the method further comprising:
generating the status data; and
transmitting the status data, wherein the RF-responsive status sensor receives an input signal comprising operational data and uses the operational data to transmit the status data using a response signal.

63. The method of monitoring a material processing system as claim in claim 61, the method further comprising:
generating status data; and
transmitting the status data, wherein the status data comprises at least one of deposition data and erosion data.

64. The method of monitoring a material processing system as claim in claim 61, wherein the method further comprises:
coupling at least one RF-responsive status sensor to a chamber component;
generating status data for the chamber component; and
transmitting the status data for the chamber component, wherein the at least one RF-responsive status sensor comprises a status sensor and a RF-responsive transmitter coupled to the status sensor.

65. The method of monitoring a material processing system as claim in claim 61, wherein the method further comprises:
coupling at least one RF-responsive status sensor to a component of an upper assembly;
generating status data for the component of the upper assembly; and
transmitting the status data for the component of the upper assembly, wherein the at least one RF-responsive status sensor comprises a status sensor and a RF-responsive transmitter coupled to the status sensor.

66. The method of monitoring a material processing system as claim in claim 61, wherein the method further comprises:
coupling at least one RF-responsive status sensor to a substrate holder;
generating status data for the substrate holder; and
transmitting the status data for the substrate holder, wherein the at least one RF-responsive status sensor comprises a status sensor and a RF-responsive transmitter coupled to the status sensor.

67. The method of monitoring a material processing system as claim in claim 61, wherein the method further comprises:
coupling at least one RF-responsive status sensor to a wafer;
generating status data for the wafer; and
transmitting the status data for the wafer, wherein the at least one RF-responsive status sensor comprises a status sensor and a RF-responsive transmitter coupled to the status sensor.

68. The method of monitoring a material processing system as claim in claim 61, wherein the method further comprises:
coupling a RF-responsive status sensor to at least one of a transfer system component, a RF system component, a gas supply system component, and an exhaust system component;
generating status data for the component; and
transmitting the status data for the component, wherein the at least one RF-responsive status sensor comprises a status sensor and a RF-responsive transmitter coupled to the status sensor.

69. The method of monitoring a material processing system as claim in claim 61, wherein the method further comprises:
coupling at least one RF-responsive status sensor to a ring;
generating status data for the ring; and
transmitting the status data for the ring, wherein the at least one RF-responsive status sensor comprises a status sensor and a RF-responsive transmitter coupled to the status sensor.

70. The method of monitoring a material processing system as claim in claim 69, wherein the ring comprises at least one of a focus ring, a shield ring, a deposition ring, an electrode ring, and an insulator ring.

71. The method of monitoring a material processing system as claim in claim 61, wherein the method further comprises:
coupling at least one RF-responsive status sensor to a plate;
generating status data for the plate; and
transmitting the status data for the plate, wherein the at least one RF-responsive status sensor comprises a status sensor and a RF-responsive transmitter coupled to the status sensor.

72. The method of monitoring a material processing system as claim in claim 71, wherein the plate comprises at least one of a baffle plate, an exhaust plate, an electrode plate, and an injection plate.

73. The method of monitoring a material processing system as claim in claim 61, wherein the method further comprises:
coupling at least one power source to a RF-responsive status sensor, wherein the RF-responsive status sensor comprises a status sensor and a RF-responsive transmitter coupled to the status sensor;
generating a DC signal; and
providing the DC signal to at least one of the RF-responsive transmitter and the status sensor.

74. The method of monitoring a material processing system as claim in claim 73, wherein the method further comprises:
generating the DC signal using at least one of a battery, filter, a RF-to-DC converter, and a DC-to-DC converter.

75. The method of monitoring a material processing system as claim in claim 61, the method further comprising:
transmitting an input signal using the SIA, the SIA comprising a transmitter, wherein the input signal comprises operational data; and
receiving the status data, wherein the SIA comprises a receiver configured to receive a response signal from at least one RF-responsive status sensor.

76. The method of monitoring a material processing system as claim in claim 75, the method further comprising:
generating the status data; and
transmitting the status data, wherein the RF-responsive status sensor receives the input signal and uses the operational data to transmit the status data using the response signal.

77. The method of monitoring a material processing system as claim in claim 61, the method further comprising:
transmitting an input signal using the SIA, the SIA comprising a transmitter, wherein the input signal comprises operational data;
receiving the input signal, wherein the RF-responsive status sensor comprises a receiver configured to receive the input signal and to obtain the operational data from the input signal;
generating the status data, wherein the RF-responsive status sensor comprises a status sensor configured to generate the status data;
transmitting the status data, wherein the RF-responsive status sensor comprises a transmitter configured to transmit the status data using a response signal; and
receiving the status data, the SIA comprising a receiver configured to receive the response signal from at least one RF-responsive status sensor.

78. The method of monitoring a material processing system as claim in claim 77, the method further comprising:
transmitting the input signal using the SIA when plasma is not being generated; and
receiving the input signal, when plasma is not being generated.

79. The method of monitoring a material processing system as claim in claim 77, the method further comprising:
generating the status data, when a process is being performed;
transmitting the response signal using the RF-responsive status sensor when plasma is not being generated; and
receiving the response signal, when plasma is not being generated.

80. The method of monitoring a material processing system as claim in claim 77, the method further comprising:
storing the status data, wherein the RF-responsive status sensor comprises a memory configured to store the status data.

81. The method of monitoring a material processing system as claim in claim 77, the method further comprising:
providing a DC signal, wherein the RF-responsive status sensor comprises a power source configured to produce the DC signal and to provide the DC signal to at least one of the RF-responsive status sensor receiver and the RF-responsive status sensor transmitter.

82. The method of monitoring a material processing system as claim in claim 81, the method further comprising:
providing a DC signal, wherein the RF-responsive status sensor comprises a power source configured to produce the DC signal by converting at least one plasma related frequency into the DC signal.

83. The method of monitoring a material processing system as claim in claim 81, the method further comprising:
providing a DC signal, wherein the RF-responsive status sensor comprises a power source configured to produce the DC signal by converting at least one non-plasma related frequency into the DC signal..

84. The method of monitoring a material processing system as claim in claim 81, the method further comprising:
providing a DC signal, wherein the RF-responsive status sensor comprises a power source configured to produce the DC signal by converting a portion of the input signal into the DC signal.

85. The method of monitoring a material processing system as claim in claim 61, the method further comprising:
stopping a process in the process tool if status data is not received from the RF-responsive status sensor.
